(19) United States
(12) Patent Application Publication
(10) Pub. No.: US 2010/0153822 A1
(43) Pub. Date: Jun. 17, 2010

(54) Constructing Forward Error Correction Codes

(75) Inventors: Cheng Huang, Redmond, WA (US); Sanjeev Mehrotra, Kirkland, WA (US); Jin Li, Sammamish, WA (US); Xiping Zuo, Kirkland, WA (US); Walid S.I. Ali, Sammamish, WA (US); Regis J. Crinon, Camas, WA (US); Ruchir Astavans, Redmond, WA (US)

Correspondence Address: MERCHANT & GOULD (MICROSOFT), P.O. BOX 2903, MINNEAPOLIS, MN, 55402-0903, US

(73) Assignee: Microsoft Corporation, Redmond, WA (US)

(21) Appl. No.: 12/335,496

(22) Filed: Dec. 15, 2008

(51) Int. Cl. H03M 13/05; G06F 11/10

(52) U.S. Cl. 714/776; 714/E11.032

(57) ABSTRACT

Construction and use of forward error correction codes is provided. A systematic MDS FEC code is obtained having a property wherein any set of contiguous or non-contiguous r packets can be lost during a data transmission of k data packets and r encoded packets and the original k packets can be recovered unambiguously. The systematic MDS FEC code is transformed into a (k+r, k) systematic MDS FEC code that guarantees at least one of the encoded packets is a parity packet. The starting systematic MDS FEC code may be Cauchy-based, and the transformation code derived from the starting Cauchy-based MDS FEC code allows for very efficient initialization, encoding and decoding operations.

### BACKGROUND

In modern distributed computing environments, data is transmitted over data networks in discrete packets of information. That is, when a given data is to be transmitted across a data network, the data is broken into a number of discrete pieces or packets, and the discrete packets are sent from a sending station to a receiving station. One problem with such data transmissions is that often one or more of the discrete packets either does not arrive at the receiving station (i.e., packet loss) or one or more packets may be corrupted during transmission so that the packets are not usable by the receiving station.

Depending on the data environment, varying degrees of data packet loss are more or less acceptable. For example, for the transmission of high resolution video, a high degree of packet loss protection may be required to deliver quality video to a receiving station. That is, in such an example high resolution video transmission, a high number of lost packets will result in unacceptable video resolution. Other types of data transmission, such as audio transmissions, may also require a high level of packet loss protection.

When packets do get lost or corrupted in transmission, various mechanisms have been employed to allow for a receiving system to receive and process a data transmission without lost packets or with an acceptable level of packet losses. According to one mechanism, when packets are transmitted to a receiving system, data is sent with the packets to inform the receiving system of the identities of each transmitted packet. If one or more packets are not received, the receiving system requests the lost packets from the transmitting system. Such a mechanism of requesting lost packets may result in all required packets being received, but such a mechanism is time consuming and requires the excessive expenditure of data transmission resources (bandwidth) and processing resources.

According to another mechanism, forward error correction (FEC) may be employed. With FEC, data is transmitted along with transmitted packets to allow a receiving system to receive all transmitted packets or an acceptable number of transmitted packets without being required to request one or more lost packets from the transmitting system. FEC may consist of sending a redundant packet for each transmitted packet so that a lost or corrupted packet may be replaced with a corresponding redundant packet. Other types of FEC allow for the sending of data that enables a receiving system to reconstruct one or more lost or corrupted packets. The sending of a redundant packet of each transmitted packet requires the expenditure of data transmission resources and processing resources, and the sending of prescribed number of redundant packets (less than the total number of transmitted packets) may still result in unacceptable packet loss at the receiving system where one or more lost packets are not included in the prescribed number of redundant packets.

It is with respect to these and other considerations that the present invention has been made.

### SUMMARY

Embodiments of the present invention solve the above and other problems by providing for construction and use of forward error correction codes. According to an embodiment, a systematic MDS FEC code is obtained having a property wherein any set of contiguous or non-contiguous r packets can be lost during a data transmission of k data packets and r encoded packets and the original k packets can be recovered unambiguously. The systematic MDS FEC code is transformed into a (k+r, k) systematic MDS FEC code that guarantees at least one of the encoded packets is a parity packet. The starting systematic MDS FEC code may be Cauchy-based, and the transformation code derived from the starting Cauchy-based MDS FEC code allows for very efficient initialization, encoding and decoding operations.

These and other features and advantages will be apparent from a reading of the following detailed description and a review of the associated drawings. It is to be understood that both the foregoing general description and the following detailed description are explanatory only and are not restrictive of the invention as claimed.

This summary is provided to introduce a selection of concepts in a simplified form that are further described below in the Detailed Description. This summary is not intended to identify key features or essential features of the claimed subject matter, nor is it intended as an aid in determining the scope of the claimed subject matter.

### BRIEF DESCRIPTION OF THE DRAWINGS

FIG. 1 is a simplified block diagram illustrating a data transmission system that may serve as an environment for embodiments of the present invention.

FIG. 2 is a logical flow diagram illustrating a method for constructing forward error correction codes.

FIG. 3 illustrates a computing operating environment in which embodiments of the present invention may be practiced.

### DETAILED DESCRIPTION

As briefly described above, embodiments of the present invention are directed to constructing forward error correction (FEC) codes for protecting against data packet losses in data transmission. The following detailed description refers to the accompanying drawings. Wherever possible, the same reference numbers are used in the drawings and the following description to refer to the same or similar elements. While embodiments of the invention may be described, modifications, adaptations, and other implementations are possible. For example, substitutions, additions, or modifications may be made to the elements illustrated in the drawings and the methods described herein may be modified by substituting, reordering, or adding stages to the disclosed methods. Accordingly, the following detailed description does not limit the invention, but instead, the proper scope of the invention is defined by the appended claims.

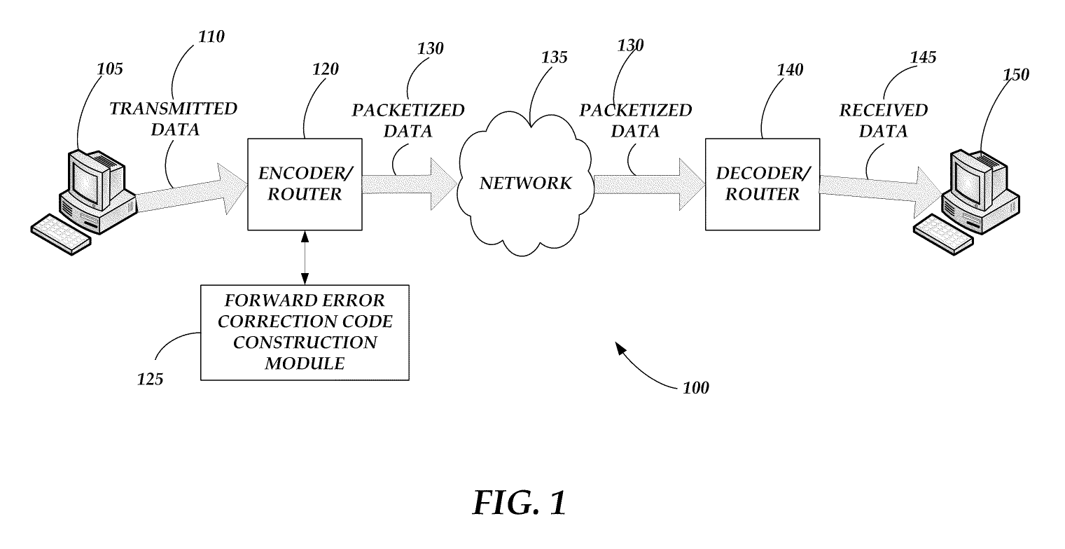

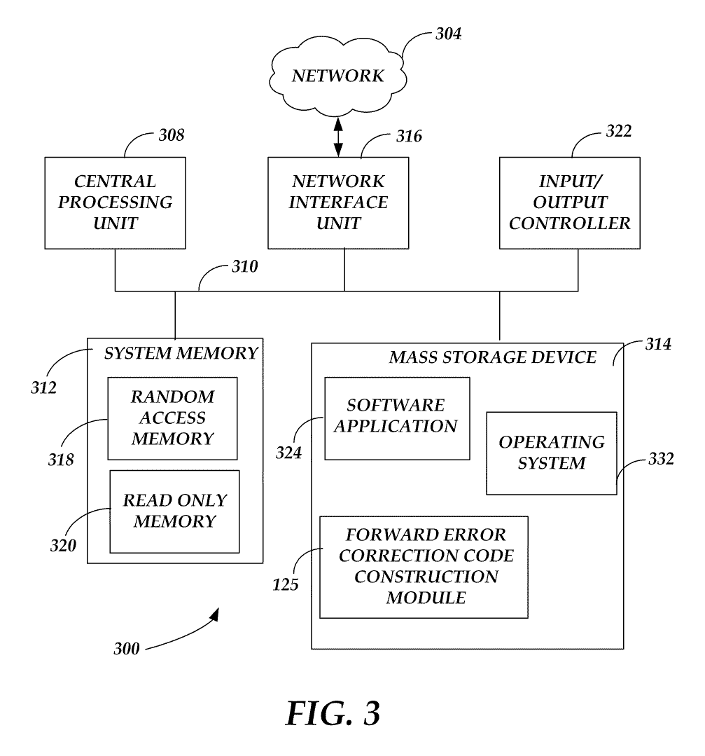

FIG. 1 is a simplified block diagram illustrating a data transmission system that may serve as an environment for embodiments of the present invention. As should be appreciated, the components and data transmission paths illustrated in and described with reference to FIG. 1 are for purposes of example only and are not limiting of the vast number of configurations that may be utilized for transmitting data as described herein. Referring to FIG. 1, a sending computing device 105 is illustrated for passing data across a network 135 to a receiving computing device 150. As should be appreciated, the sending computing device 105 may be a general-purpose computer, as illustrated in and described below with reference to FIG. 3, with which a variety of data may be sent to a receiving computing device 150. For example, the computing devices 105, 150 may be in the form of a personal computer, a mobile computing device, for example, a personal digital assistant or mobile telephone. Alternatively, the computing devices 105, 150 may be devices for sending other forms of data, such as video, audio, or combinations of one or more data types. Types of data that may be transmitted across the network 135 may include electronic mail messages, electronic documents and files, web pages, audio streams, video streams, and the like.

Referring still to FIG. 1, in a typical data transmission environment, transmitted data 110 is passed from a sending device 105 through an encoder/router 120. The transmitting data 110 is a stream of data representing whatever is being transmitted, for example, an electronic mail message, a videoconference stream, and an audio stream, etc. At the encoder/router 120, the data stream 110 is broken into a number of discrete pieces of data often referred to as packets. As should be appreciated, the encoding functionality of the encoder/router 120 may reside in the sending device 105 separate from the router, or encoding may be performed on a standalone encoding device and routing may be performed on yet a different standalone routing device.

Each packet may contain a prescribed amount of data, for example, 1,000 to 2,000 bytes of data. Each packet of data comprising the transmitted data 110 is then encoded with identifying information, sometimes referred to as a wrapper, to help the packet arrive at the intended address. For example, each packet may be encoded with the sending station's (computer 105) address, the receiving station's (computer 150) address, the individual packet's position in the data stream relative to other packets, and a total number of packets that are being sent. As should be appreciated, a variety of additional information may be encoded onto each packet as desired to assist in the efficient transmission of the packets to the receiving station 150.

Each of the packets comprising the packetized data 130 is sent across a network 135 in order to ultimately get the data to the receiving station 150. The network 135 may be any system of communication paths across which data may be transmitted from one station to another. For example, the network 135 may be in the form of the Internet, a corporate intranet, or even a single wireline or wireless path over which packetized data may be sent.

At the receiving end, the packetized data 130 passes through a decoder/router 140. The decoder/router 140 receives each packet, and based on the information encoded onto each packet, the decoder/router 140 assembles the packetized data 130 back into a stream of data 145 that may be presented to and processed by the receiving station (computer 150). For example, if the transmitted data 110 is in the form of a video conference transmission, then the data representing the video is packetized, transmitted across the network 135, and then is reformed into a video stream 145 by joining each received packet in the proper order for presenting the received video stream at the receiving station 150.

A problem with such a data transmission environment is that when packetized data is passed across the network 135, often one or more individual packets are lost or corrupted in some manner, and thus are not available to the decoder/router 140 for re-assembly into the received data stream 145. Depending on the requirements of a given system, more or less packet loss is acceptable. For example, for high resolution video transmission, a high number of packet losses will result in unacceptable resolution at the receiving station (computer 150).

The foregoing discussion provides one operating environment wherein a data transmission system is described in which packet loss and recovery may occur. As should be appreciated, however, embodiments of the present invention are equally applicable to other environments where packet loss may occur and where loss recovery is required. For example, embodiments of the invention are applicable to one or more data storage systems in which packet losses may occur during storage and where packet recovery may be enabled.

According to embodiments of the invention, a forward error correction (FEC) model may be employed for causing additional packets to be transmitted across the network 135 with the packetized data 130 such that the additional packets may be used by the decoder/router 140 for replacing packets lost from the packetized data 130 during the transmission. That is, if the total number of packets to be transmitted across the network equals k packets, then according to a forward error correction (FEC) model, an additional r packets may be transmitted with the k packets (k+r packets) to protect against r packet losses during transmission of the packets across the network 135.

Referring still to FIG. 1, the forward error correction (FEC) construction module 125 is a software module containing sufficient computer executable instructions for constructing FEC codes for allowing a recovery of an arbitrary number of lost packets. For example, consider that 10 packets are transmitted across a network 135 (k packets=10). If a given packet is lost, there is a need to recover the lost data at the receiving station 150. As discussed above, according to FEC, instead of sending k packets across the network, more than k packets are sent so that the extra packets may be used to carry information for recovering lost packets on the receiving end. For example, instead of sending 10 packets, 12 packets may be sent, and if two of the original 10 packets are lost, then the extra two packets sent (12−10=2) may be used to recover the lost information.

According to an embodiment, a (n, k) forward error correction (FEC) code defines a mathematical transformation from k original packets to n coded packets of equal size (n>=k). The transformation of a linear (n, k) FEC code can be represented using a matrix multiplication as C=DG, where C, D and G are code matrix, data matrix and generator matrix, respectively. More specifically, the data matrix D may consist of k vectors, where each vector d_i (1<=i<=k) is a data packet. Similarly, the code matrix C may consist of n vectors, each vector c_j (1<=j<=n) being a coded packet. The generator matrix G is a k x n matrix, and at a high level, the quantity n - k is representative of the level of redundancy added to the original data to facilitate reconstruction at the receiving end in case of data packet loss. The transformation (encoding) may be represented in the following example expression 1.1.

$$[ \begin{matrix}c\_ 1 & … & c\_k & c\_ \{ k + 1 \} & … & c\_n\end{matrix} ] = {[ \begin{matrix}d\_ 1 & … & d\_k\end{matrix} ] [ \begin{matrix}g\_ \{ 1 , 1 \} & … & g\_ \{ 1 , k \} & g\_ \{ 1 , k + 1 \} & … & g\_ \{ 1 , n \} \\ ⋮ & ⋱ & ⋮ & ⋮ & ⋱ & ⋮ \\ g\_ \{ k , 1 \} & … & g\_ \{ k , k \} & g\_ \{ k , k + 1 \} & … & g\_ \{ k , n \}\end{matrix} ]}_{k \times n} . \qquad ( 1.1 )$$

As set out above, k packets are illustrated for passing across a given network. The notations c_1 to c_k are used to represent the packets to be sent across the network 135. On the right side of the example expression 1.1, the notations d_1 to d_k are used to represent coded packets to be sent in the transmission, where each packet d_1 to d_k may be a byte of data, several bytes of data, or thousands of bytes of data, depending on the amount of data included in each discrete data packet. According to a FEC model, an FEC coding of the packets to be transmitted may be represented as a matrix transformation. For example, as set out above, the data d_1 to d_k is transformed into another set of FEC coded packets c_1 to c_k. Accordingly, when the desired packets are transmitted, instead of sending the original packets d_1 to d_k, the transformed FEC coded packets c_1 to c_k are transmitted up to c_n packets.

According to an embodiment, a maximum distance separable (MDS) FEC code is an FEC code with special properties such that any set of contiguous or non-contiguous k coded packets can recover the original k packets, meaning that any combination of (n−k) packets can be lost and the original k packets can still be recovered unambiguously. In matrix terms, this is equivalent to saying that any k columns of the generator matrix G, illustrated below as example matrix 1.2, are linearly independent (or form an invertible matrix).

A systematic MDS code is a NDS code where the first k columns of the generator matrix form an identity matrix. If the FEC code has MDS properties, then only k+r packets must be sent across the network to protect r losses. Following from the mathematical notation (n, k) FEC code set out above, if the (n, k) FEC code is an MDS FEC code, then n=k+r for protecting r losses.

According to some data transmission systems, a simple FEC code may be utilized where the coded packets consist of all the original packets plus an additional parity packet. Such a FEC code is illustrated below as matrix 1.2 and may be described as a (k+1, k) systematic MDS code. In the generator matrix G (1.2), a matrix is constructed with k rows by (k+1) columns and shows all the coefficients listed in the matrix. Essentially, the matrix 1.2 is an identity matrix plus an extra column (column 0, 1). The extra column is a sum of all the elements of the array. For example, for elements d_1, d_2 to d_k, the extra column would be a sum of these elements, which allows for the generation of the extra packet to be transmitted.

$$G = {[ \begin{matrix}1 & 0 & … & 0 & 1 \\ 0 & 1 & … & 0 & 1 \\ ⋮ & ⋮ & ⋱ & ⋮ & ⋮ \\ 0 & 0 & … & 1 & 1\end{matrix} ]}_{k \times ( k + 1 )} . \qquad ( 1.2 )$$

According to one embodiment, this simple FEC code may be implemented by applying and XOR operation to the k packets to generate one extra packet to protect one packet loss to create a (k+1, k) FEC code. As applications and data are passed between transmission environments, one extra packet may not be able to provide adequate loss protection, and protection against an arbitrary number of packet losses may be desired while maintaining an FEC code that is compatible with the simple (k+1, k) FEC code described above. Thus, according to an embodiment, it is desirable to construct a systematic MDS FEC code that is compatible with the (k+1, k) systematic FEC code described above as matrix 1.2. That is, it is desirable to generate an MDS FEC code where (n−k) could be larger than 1 and that is compatible with the (k+1, k) code described above.

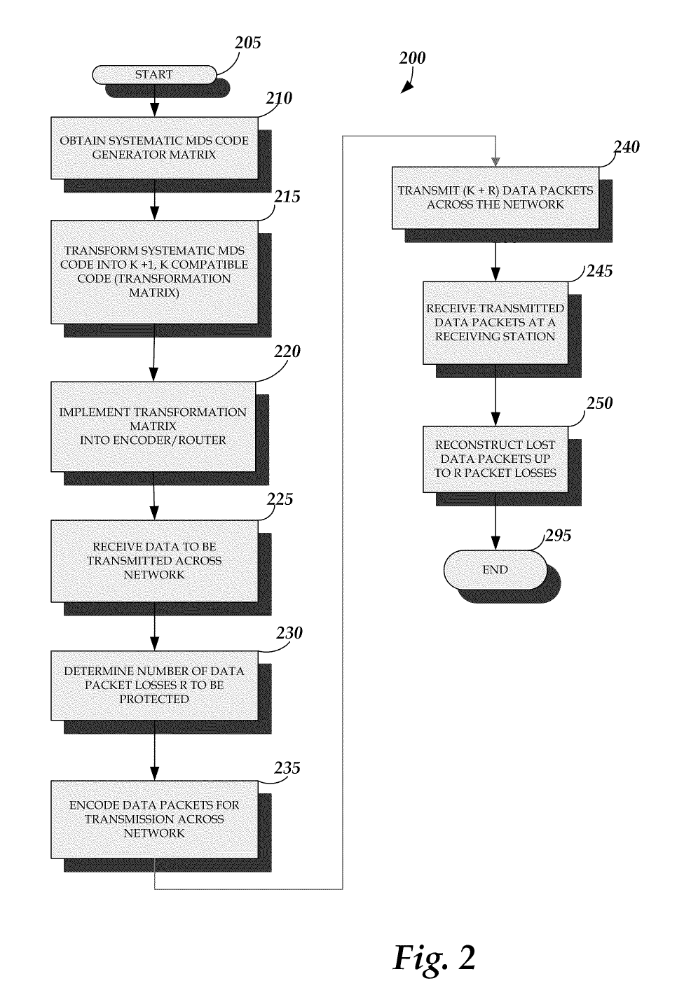

FIG. 2 is a logical flow diagram illustrating a method for constructing forward error correction codes. For purposes of illustration, the construction of an MDS FEC code that is compatible with the (k+1, k) systematic MDS code described above as matrix 1.2 will be described with reference to FIG. 2 and with reference to matrices 1.3 and 1.4 set out below. The routine 200 illustrated in FIG. 2 begins at start operation 205 and proceeds to operation 210. At operation 210, a starting systematic MDS FEC code 1.3 (generator matrix) is obtained.

According to one embodiment, the systematic MDS FEC code that is compatible with the (k+1, k) systematic MDS code may be generated by constructing a k×n generator matrix G, such that any k columns are linearly independent and the first (k+1) columns are the same as those illustrated in matrix 1.2. An example generator matrix G, shown below as matrix 1.3, illustrates any systematic MDS code of a general arbitrary matrix made up of two parts. The left side of matrix 1.3 illustrates an identity matrix and the right side may include arbitrary coefficients. For additional information on the construction of a generator matrix such as the matrix 1.3, see M. O. Rabin, “Efficient Dispersal of Information for Security, Load Balancing, and Fault Tolerance,” J. ACM, April 1989 which is incorporated herein by reference.

The example generator matrix G (systematic MDS code 1.3) is not compatible with the (k+1, k) systematic MDS code described above as matrix 1.2. According to an embodiment, it is desirable to transform the matrix 1.3 into a (k+1, k) systematic MDS code described above as matrix 1.2 so that the resulting MDS FEC code guarantees at least one extra protection packet. That is, it is desirable to transform the systematic MDS code so that it has the (k+1, k) property described above while keeping the MDS property such that if we remove any k columns from the matrix, the matrix formed by these k columns will still be non-singular.

As discussed above, the importance of this mathematical transformation is to construct an MDS FEC code that allows for combating r packet losses by sending k+r packets across the network while maintaining the (k+1, k) systematic MDS code property described above with respect to matrix 1.2. By not having to send more than r packets to protect against r losses, transmission bandwidth is saved and processing time is reduced.

Referring still to FIG. 2, at transformation operation 215, the generator matrix 1.3 is transformed into the transformation matrix 1.4. The linear transformation illustrated and described below may be used to convert any systematic MDS code into a code that is compatible with the (k+1, k) systematic MDS code described above as matrix 1.2. As described above, the generator matrix G, illustrated as matrix 1.3 above, takes an arbitrary form and is shown having two parts. The left part of the matrix is in the form of an identity matrix and right part may include arbitrary coefficients.

Given a generator matrix G of a systematic MDS code,

$$G = {[ \begin{matrix}1 & 0 & … & 0 & g\_ \{ 1 , k + 1 \} & g\_ \{ 1 , k + 2 \} & … & g\_ \{ 1 , n \} \\ 0 & 1 & … & 0 & g\_ \{ 2 , k + 1 \} & g\_ \{ 2 , k + 2 \} & … & g\_ \{ 2 , n \} \\ ⋮ & ⋮ & ⋱ & ⋮ & ⋮ & ⋮ & ⋱ & ⋮ \\ 0 & 0 & … & 1 & g\_ \{ k , k + 1 \} & g\_ \{ k , k + 2 \} & … & g\_ \{ k , n \}\end{matrix} ]}_{k \times n} , \qquad ( 1.3 )$$

we can obtain a new matrix G′ (matrix 1.4) as

$$\begin{matrix}{G}^{′} = {[ \begin{matrix}\frac{1}{{g}_{\{ 1 , k + 1 \}}} & 0 & … & 0 \\ 0 & \frac{1}{{g}_{\{ 2 , k + 1 \}}} & … & 0 \\ ⋮ & ⋮ & ⋱ & ⋮ \\ 0 & 0 & … & \frac{1}{{g}_{\{ k , k + 1 \}}}\end{matrix} ]}_{k \times k} \times \\ {[ \begin{matrix}1 & 0 & … & 0 & {g}_{\{ 1 , k \}} & {g}_{\{ 1 , k + 1 \}} & … & {g}_{\{ 1 , n \}} \\ 0 & 1 & … & 0 & {g}_{\{ 2 , k \}} & {g}_{\{ 2 , k + 1 \}} & … & {g}_{\{ 2 , n \}} \\ ⋮ & ⋮ & ⋱ & ⋮ & ⋮ & ⋮ & ⋱ & ⋮ \\ 0 & 0 & … & 1 & {g}_{\{ k , k \}} & {g}_{\{ k , k + 1 \}} & … & {g}_{\{ k , n \}}\end{matrix} ]}_{k \times n} \times \\ {[ \begin{matrix}g\_ \{ 1 , k \vert 1 \} & 0 & … & 0 & 0 & … & 0 \\ 0 & g\_ \{ 2 , k + 1 \} & … & 0 & 0 & … & 0 \\ ⋮ & ⋮ & ⋱ & ⋮ & ⋮ & ⋱ & ⋮ \\ 0 & 0 & … & g\_ \{ k , k + 1 \} & 0 & … & 0 \\ 0 & 0 & … & 0 & 1 & … & 0 \\ 0 & 0 & ⋱ & ⋮ & ⋮ & ⋱ & ⋮ \\ 0 & 0 & … & 0 & 0 & … & 1\end{matrix} ]}_{n \times n} \\ = {[ \begin{matrix}1 & 0 & … & 0 & 1 & \frac{g \{ 1 , k + 2 \}}{g \{ 1 , k + 1 \}} & … & \frac{g \{ 1 , n \}}{g \{ 1 , k + n \}} \\ 0 & 1 & … & 0 & 1 & \frac{g \{ 2 , k + 2 \}}{g \{ 2 , k + 1 \}} & … & \frac{g \{ 2 , n \}}{g \{ 2 , k + 1 \}} \\ ⋮ & ⋮ & ⋱ & ⋮ & ⋮ & ⋮ & ⋱ & ⋮ \\ 0 & 0 & … & 1 & 1 & \frac{g \{ k , k + 2 \}}{g \{ k , k + 1 \}} & … & \frac{g \{ k , n \}}{g \{ k , k + 1 \}}\end{matrix} ]}_{k \times n .} .\end{matrix} \qquad ( 1.4 )$$

Referring to the matrix 1.3 the arbitrary matrix form shows a first row having 1, 0, 0 of the left side and g_{—}{1, k+1}, g_{—}{1, k+2} . . . g_{—}{1, n} on the right. After the mathematical operation, illustrated above, the resulting matrix G′ still has 1, 0, 0 on the left and the elements on the right of the rows have been divided by the first element g_{—}{1, k+1} so that the k+1 entry becomes 1 and then the next entry is the original entry divided by g_{—}{1, k+1}, and so on, to arrive at the matrix G′ (matrix 1.4) that is an MDS FEC code with the (k+1, k) systematic MDS code property described above with respect to matrix 1.2.

Next, two Lemmas are proven, which together ensure that G′ (matrix 1.4) indeed defines a MDS code the (k+1, k) systematic MDS code property described above with respect to matrix 1.2.

Lemma 1: For any given systematic MDS code, all entries in the (k+1)̂{th} column of the generator matrix G are non-zero, i.e., g_{i, k+1}≠0 (1<=i<=k).

Proof of Lemma 1: Lemma 1 can be proved by contradiction. Assume the î{th} entry is in fact zero, i.e., g_{i, k+1}=0. Now, consider a particular loss pattern, where there are (n−k) missing packets—the î{th} data packet and all FEC packets other than the 1^{st} FEC packet. Based on the MDS property, this loss pattern is recoverable as there are k packets remaining. However, g_{i, k+1}=0 implies that the calculation of 1^{st} FEC does not involve the î{th} data packet. Hence, it can not be used to recover the î{th} data packet. This is a contradiction and thus the proof is completed. See C. Huang, M. Chen, and J. Li, “Pyramid Codes: Flexible Schemes to Trade Space for Access Efficiency in Reliable Data Storage Systems,” IEEE NCA, July 2007 which is incorporated herein by reference.

Lemma 2: Given the generator matrix G of any systematic MDS code, the new matrix G′ obtained from transformation (matrix 1.4) has the property that any k columns are linearly independent.

Proof of Lemma 2: G′ is obtained from G by left multiplication (and right multiplication) of diagonal matrices with non-zero entries (from Lemma 1). The independence of any k columns in G directly results in the independence of any k columns in G′.

Based on the above two Lemmas, the following theorem may be concluded. Given the generator matrix G of any systematic MDS code, the new matrix G′ obtained from transformation (e.g., operation resulting in matrix 1.4) defines a MDS FEC code G′ with the (k+1, k) systematic MDS code property described above with respect to matrix 1.2. The resulting matrix G′ produces a simpler more efficient forward error code in terms of both computation complexity and processing efficiency, as discussed further below.

Referring still to FIG. 2, after transformation of the generator matrix 1.3 into the transformation matrix 1.4 having the desired properties of a MDS FEC code with the (k+1, k) systematic MDS code property described above with respect to matrix 1.2, the resulting code may be implemented into an encoder/router device 120 at operation 220. Implementation of the transformed code into the encoder/router device 120 allows for packetized data 130 to be transmitted across the network 135 such that a desired number of packets (k+r) are transmitted for protecting against an arbitrary number of r packet losses at the receiving decoder/router 140.

After implementation of the transformed code into an encoder/router 120, data to be transmitted may be received at the encoder at operation 225. At operation 230, a number of packet losses r to be protected against loss may be determined. At operation 235, the data received at the encoder is packetized, and at operation 240, (k+r) packets are transmitted across the network 135, where the number of packets r is determined in accordance with the implemented transformation matrix 1.4. At operation 245, the packets are received at the decoder/router 140, and at operation 250, lost packets are recovered using the r encoded packets that were transmitted along with the original k data packets. Because the transformation matrix 1.4, includes the (k+1, k) systematic MDS code property described above with respect to matrix 1.2, at least one protected packet is guaranteed regardless of the value of r.

Based on the foregoing, it can be seen that forward error correction may be provided according to embodiments of the invention where an encoder 120 may be populated with a forward error correction (FEC) code operable to enable a recovery of a loss of up to all of a set of transmitted packets comprising a set of contiguous or non-contiguous n packets that consist of k data packets and r encoded packets, where the FEC code is transformed such that at least one of the encoded packets is a parity packet which is the XOR of all k data packets. The resulting transformed FEC code is operable to enable a recovery of a loss of up to all r packets. When the FEC code is used in a data transmission system and the original k data packets and the r encoded packets are transmitted over a network where the original k data packets and the r encoded packets are subjected to network packet losses, the original k data packets and the r encoded packets are recoverable as long as fewer than r packets are lost in the transmission. The resulting MDS FEC code may be expressed in matrix terms as a (k+r, k) systematic MDS code, and a matrix representing the (k+r, k) systematic MDS FEC code is constructed with k rows by (k+r) columns, wherein the k+1 column in the matrix represents the parity packet. Thus, according to the transformed MDS FEC code, a transmission of k data packets and r encoded packets is enabled. During transmission, of the k+r total packets (data packets+encoded packets), the transmission network may lose any 0, 1, 2, 3 . . . up to r packets, and the receiving station 150 may still recover all k data packets. If the loss is more than r+1 packets (where the +1 is recovered by the parity packet), then the receiving station may recover equal to or less than k−1 packets among the packet set. The routine 200 ends at operation 295.

As described above, an arbitrary generator matrix G, as illustrated in matrix 1.3, may be transformed into an MDS FEC code G′ with the (k+1, k) systematic MDS code property described above with respect to matrix 1.2. According to another embodiment, a Cauchy-based matrix G of the form illustrated as matrix 1.5 below is utilized as a generator matrix that has the desired MDS properties, but that does not have the desired (k+1, k) systematic MDS code property described above with respect to matrix 1.2. For more information on the Cauchy-based generator matrix G (1.5), see M. O. Rabin, “Efficient Dispersal of Information for Security, Load Balancing, and Fault Tolerance,” J. ACM, April 1989 and J. Blomer, M. Kalfane, R. Karp, M. Karpinski, M. Luby, D. Zeckerman, “An XOR-Based Erasure Resilient Coding Scheme,” Technical Report TR-95-48, UC Berkeley, 1995, which are incorporated herein by reference.

$$G = {[ \begin{matrix}1 & 0 & … & 0 & \frac{1}{1 + ( k + 1 )} & \frac{1}{1 + ( k + 2 )} & … & \frac{1}{1 + n} \\ 0 & 1 & … & 0 & \frac{1}{2 + ( k + 1 )} & \frac{1}{2 + ( k + 2 )} & … & \frac{1}{2 + n} \\ ⋮ & ⋮ & ⋱ & ⋮ & ⋮ & ⋮ & ⋱ & ⋮ \\ 0 & 0 & … & 1 & \frac{1}{k + ( k + 1 )} & \frac{1}{k + ( k + 2 )} & … & \frac{1}{k + n}\end{matrix} ]}_{k \times n} . \qquad ( 1.5 )$$

Applying the transformation logic described above in the transformation of generator matrix 1.3 to matrix 1.4, the following MDS FEC code 1.6 may be generated that has both the desired MDS properties and the desired (k+1, k) systematic MDS code property described above with respect to matrix 1.2.

$${G}^{′} = {[ \begin{matrix}1 & 0 & … & 0 & 1 & \frac{1 + ( k + 1 )}{1 + ( k + 2 )} & … & \frac{1 + ( k + 1 )}{1 + n} \\ 0 & 1 & … & 0 & 1 & \frac{2 + ( k + 1 )}{2 + ( k + 2 )} & … & \frac{2 + ( k + 1 )}{2 + n} \\ ⋮ & ⋮ & ⋱ & ⋮ & ⋮ & ⋮ & ⋱ & ⋮ \\ 0 & 0 & … & 1 & 1 & \frac{k + ( k + 1 )}{k + ( k + 2 )} & … & \frac{k + ( k + 1 )}{k + n}\end{matrix} ]}_{k \times n} . \qquad ( 1.6 )$$

According to this embodiment, starting with the Cauchy-based matrix, such as the example matrix 1.5, provides a generator matrix having the desired MDS properties and that can be readily transformed into a form G′ with the desired (k+1, k) systematic MDS code property described above with respect to matrix 1.2. That is, the resulting matrix 1.6 has 0, 1 in the k+1 column, and then based on the proofs discussed above, it can be readily shown that the resulting matrix 1.6 maintains the MDS property.

For testing the performance of the Cauchy-based MDS FEC code illustrated and described above with reference to matrix 1.6, the initialization, encoding and decoding performance of the Cauchy-based MDS FEC code was compared against the initialization, encoding and decoding performances of three other codes. Performance testing data is provided below in Table 1. A first tested code included a traditional Vandermonde-based MDS code, labeled Case RS0 below. See M. O. Rabin, “Efficient Dispersal of Information for Security, Load Balancing, and Fault Tolerance,” J. ACM, April 1989. A second tested code included a simple (k+1, k) FEC code that protects up to 3 packet losses, labeled Case RS1 below. A third tested code included a (k+1, k) systematic MDS code constructed using a Schwarz algorithm, labeled Case RS2 below. See T. Schwarz, “Generalized Reed Solomon Codes For Fault Tolerance in Scalable Distributed Data Structures,” WDAS, 2002. A fourth tested code included the Cauchy-based MDS FEC code of the present invention that is illustrated and described above with reference to matrix 1.6, labeled Case RS3 below. For purposes of testing, performance was measured on an example computer 300 (illustrated and described below with respect to FIG. 3) with a 3.2 GHz CPU, 4 GB RAM and running WINDOWS® XP operating system (Microsoft Corporation). The parameters of the comparison testing were: n=43, k=40, packet size=1024. All results were averaged over 100 testing rounds.

As mentioned above, performance comparison of the Cauchy-based MDS FEC code of the present invention against the three other example codes was based on initialization, encoding and decoding performances of the tested codes. For purposes of the conducted testing, initialization included processing time required to construct each code type into a form consistent with the generator matrix 1.3 described above. The encoding time includes the amount of processing time to generate k+r packets, where k equals the number of packets to be transmitted across the network and r equals the number of additional packets required for protecting r lost packets according to the tested code model. The decoding time includes the amount of processing required to recover r lost packets at the decoder/router 140 according to the tested model.

TABLE 1

| | | | (k + 1, k) | |
|---|---|---|---|---|
| | | | Systematic MDS | |
| | | | Code | |
| FEC | | | Compatibility | |
| Model | Description | FEC property | (Matrix 1.2) | Performance |
| Case | Traditional | MDS with arbitrary | No | Initialization = 306.129 |
| RS0 | Vandermonde | number of parities | | Encoding = 270.514 |
| | | | | Decoding = 282.47 |
| Case | Systematic | MDS up to 3 | Yes | Initialization = 3.39763 |
| RS1 | Vandermonde | parities (lose MDS | | Encoding = 248.546 |
| | | beyond 3 parities) | | Decoding = 258.327 |
| Case | Schwarz | MDS with arbitrary | Yes | Initialization = 1340.52 |
| RS2 | Algorithm | number of parities | | Encoding = 257.754 |
| | | | | Decoding = 253.043 |
| Case | Cauchy-based | MDS with arbitrary | Yes | Initialization = 3.44928 |
| RS3 | MDS FEC | number of parities | | Encoding = 260.172 |
| | Code (Matrix | | | Decoding = 265.802 |
| | 1.6) | | | |

Referring now to Table 1, the first tested model, labeled as Case RS0, was a traditional MDS FEC code, and while this tested code included the desired MDS properties, the Case RS0 code did not have the desired (k+1, k) systematic MDS code property described above with respect to matrix 1.2. In addition, the initialization time of 306.129 milliseconds was very inefficient as compared to the initialization efficiency of the Case RS3 code of the present invention.

The second tested code, labeled as Case RS1, included the desired MDS properties, but only included the desired (k+1, k) systematic MDS code property up to an additional r=3 packets (i.e., k+1, k+2, k+3). That is, the second tested model failed to protect against an arbitrary number of packet losses as was the case with the Case RS3 code of the present invention. Thus, with the Case RS1 tested model, desired MDS properties are lost after 3 protected packet losses.

The third tested code, labeled as Case RS2, included the desired MDS properties and the desired (k+1, k) systematic MDS code property described above with respect to matrix 1.2. However, as set out in Table 1, above, the initialization time required for the Case RS2 code was excessive as compared to the initialization efficiency of the Case RS3 code of the present invention. That is, the initialization time for the Case RS2 code was 1340.52 milliseconds as compared to 3.44928 milliseconds for the Case RS3 code of the present invention.

As should be appreciated the processing time required for initialization of an FEC code is very important because when k and r packets are sent across any network 135, the parameters of k and r may change on a regular basis depending on the characteristics of the network across which data is transmitted. That is, as network configurations and performance characteristics vary, the value of r for protecting r losses will likewise vary. Thus, initialization must be re-performed each time the parameters k and r change. Thus, initialization time becomes an important efficiency aspect of the utilized FEC code model.

Referring still to Table 1, the fourth tested code, labeled as Case RS3, included the Cauchy-based MDS FEC code of the present invention. The Case RS3 code included both the desired MDS properties and the desired (k+1, k) systematic MDS code property described above with respect to matrix 1.2. That is, the Case RS3 code included the desired MDS properties and protected against an arbitrary number of packet losses. In addition, the initialization, encoding and decoding times were very good as compared to the other tested codes. According to an embodiment, the initialization time for the RS3 code of the present invention is significantly better than the initialization time of the RS2 code because the starting generator matrix of the form illustrated as matrix 1.5 and because of the transformation of the starting generator matrix to provide for the desired (k+1, k) systematic MDS code property as illustrated as matrix 1.6. In addition, given that a first data packet is guaranteed as a simple XOR operation in Case RS3, the first FEC packet may be encoded using a simple XOR operation to improve performance of the Case RS3 code even further because the XOR computation may be readily optimized. With respect to the Case RS3 code, decoding efficiency may be improved by utilizing a simple XOR operation to recover a single data packet in cases where a single data packet is lost.

According to an embodiment, the MDS FEC codes of the present invention (e.g., codes 1.4 and 1.6) are extensible where different receiving decoders/routers have different capabilities. For example, for the same k packets, the first r FEC packets generated by a (k+r, k) FEC code and a (k+r′, k) FEC code, where r′>r, the two FEC codes may be identical. Likewise, the first r′ FEC packets generated by a (k+r′, k) FEC code may be identical to the first r′ FEC packets generated by a (k+r, k) FEC code when r>r′. The generator matrix columns used to compute FEC packets are independent of n. This extensibility allows a (k+r, k) FEC code be applied to the packets at one time and expanded or reduced to a (k+r′, k) FEC code at a later time, without decoding and re-encoding. In practical situations, this means that in complex delivery networks, an original set of FEC packets produced by a media source (e.g., encoder/router 120) may be readily either reduced or increased to adapt to the characteristics of different decoders/routers at a receiving end of a network transmission, particularly where a first decoder has one historical packet loss characteristic and a second decoder has a different (higher or lower) packet loss characteristic. In such a case, the increase or decrease in FEC packets may be done by an entity different from where the original FEC code is applied. Such an entity can be any suitable device or system operable for routing data to various and differently configured receiving stations in a network.

### Example Computing Operating Environment

Referring now to FIG. 3, the following discussion is intended to provide a brief, general description of a suitable computing environment in which embodiments of the invention may be implemented. While the invention will be described in the general context of program modules that execute in conjunction with program modules that run on an operating system on a personal computer, those skilled in the art will recognize that the invention may also be implemented in combination with other types of computer systems and program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

Referring now to FIG. 3, an illustrative operating environment for embodiments of the invention will be described. As shown in FIG. 3, computer 300 comprises a general purpose desktop, laptop, handheld, mobile or other type of computer (computing device) capable of executing one or more application programs. The computer 300 includes at least one central processing unit 308 (“CPU”), a system memory 312, including a random access memory 318 (“RAM”) and a read-only memory (“ROM”) 320, and a system bus 310 that couples the memory to the CPU 308. A basic input/output system containing the basic routines that help to transfer information between elements within the computer, such as during startup, is stored in the ROM 320. The computer 302 further includes a mass storage device 314 for storing an operating system 332, application programs, and other program modules.

The mass storage device 314 is connected to the CPU 308 through a mass storage controller (not shown) connected to the bus 310. The mass storage device 314 and its associated computer-readable media provide non-volatile storage for the computer 300. Although the description of computer-readable media contained herein refers to a mass storage device, such as a hard disk or CD-ROM drive, it should be appreciated by those skilled in the art that computer-readable media can be any available media that can be accessed or utilized by the computer 300.

By way of example, and not limitation, computer-readable media may comprise computer storage media and communication media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, digital versatile disks (“DVD”), or other optical storage, magnetic cassettes, magnetic tape, magnetic disk storage or other magnetic storage devices, or any other medium which can be used to store the desired information and which can be accessed by the computer 300.

According to various embodiments of the invention, the computer 300 may operate in a networked environment using logical connections to remote computers through a network 304, such as a local network, the Internet, etc. for example. The computer 302 may connect to the network 304 through a network interface unit 316 connected to the bus 310. It should be appreciated that the network interface unit 316 may also be utilized to connect to other types of networks and remote computing systems. The computer 300 may also include an input/output controller 322 for receiving and processing input from a number of other devices, including a keyboard, mouse, etc. (not shown). Similarly, an input/output controller 322 may provide output to a display screen, a printer, or other type of output device.

As mentioned briefly above, a number of program modules and data files may be stored in the mass storage device 314 and RAM 318 of the computer 300, including an operating system 332 suitable for controlling the operation of a networked personal computer, such as the WINDOWS® operating systems from MICROSOFT CORPORATION of Redmond, Wash. The mass storage device 314 and RAM 318 may also store one or more program modules. In particular, the mass storage device 314 and the RAM 318 may store application programs, such as a software application 324, for example, a word processing application, a spreadsheet application, a slide presentation application, a database application, etc.

According to embodiments of the present invention, the forward error correction (FEC) construction module 125 is a software module containing sufficient computer executable instructions for constructing FEC codes for allowing a recovery of an arbitrary number of lost packets, as described above with reference to FIGS. 1 and 2.

It should be appreciated that various embodiments of the present invention may be implemented (1) as a sequence of computer implemented acts or program modules running on a computing system and/or (2) as interconnected machine logic circuits or circuit modules within the computing system. The implementation is a matter of choice dependent on the performance requirements of the computing system implementing the invention. Accordingly, logical operations including related algorithms can be referred to variously as operations, structural devices, acts or modules. It will be recognized by one skilled in the art that these operations, structural devices, acts and modules may be implemented in software, firmware, special purpose digital logic, and any combination thereof without deviating from the spirit and scope of the present invention as recited within the claims set forth herein.

Although the invention has been described in connection with various embodiments, those of ordinary skill in the art will understand that many modifications may be made thereto within the scope of the claims that follow.

What is claimed is:

1. A method of providing forward error correction, comprising:
populating an encoder with a forward error correction (FEC) code operable to enable a recovery of a loss of up to all of a set of packets comprising a set of contiguous or non-contiguous n packets, the n packets consisting of k data packets and r encoded packets;
transforming the FEC code such that at least one of the encoded packets in the transformed FEC code is a parity packet, which is the XOR of all k data packets; and
wherein the transformed FEC code is operable to enable a recovery of a loss of up to r packets.

2. The method of claim 1, wherein if the FEC code is used in a data transmission system wherein the original k data packets and the r encoded packets are transmitted over a network; and
if the original k data packets and the r encoded packets are subjected to network packet losses;
the original k data packets and the r encoded packets are recoverable as long as less than or equal to r packets are lost in the transmission.

3. The method of claim 1, wherein the MDS FEC code may be expressed in matrix terms as a (k+r, k) systematic MDS code and wherein a matrix representing the (k+r, k) systematic MDS code is constructed with k rows by (k+r) columns, wherein a k+1 column represents the parity packet.

4. The method of claim 1, wherein the MDS FEC code is operable to enable a recovery of a loss of up to all r packets comprising a transmitted set of contiguous or non-contiguous n data packets may take the form of a generator matrix of the form
$$G = {[ \begin{matrix}1 & 0 & … & 0 & g\_ \{ 1 , k + 1 \} & g\_ \{ 1 , k + 2 \} & … & g\_ \{ 1 , n \} \\ 0 & 1 & … & 0 & g\_ \{ 2 , k + 1 \} & g\_ \{ 2 , k + 2 \} & … & g\_ \{ 2 , n \} \\ ⋮ & ⋮ & ⋱ & ⋮ & ⋮ & ⋮ & ⋱ & ⋮ \\ 0 & 0 & … & 1 & g\_ \{ k , k + 1 \} & g\_ \{ k , k + 2 \} & … & g\_ \{ k , n \}\end{matrix} ]}_{k \times n .} ,$$

5. The method of claim 4, wherein after transforming the MDS FEC code such that the MDS FEC code is further consist of an additional parity packet, a resulting transformed MDS FEC code may take the form of a transformation matrix of the form
$${[ \begin{matrix}1 & 0 & … & 0 & 1 & \frac{g \{ 1 , k + 2 \}}{g \{ 1 , k + 1 \}} & … & \frac{g \{ 1 , n \}}{g \{ 1 , k + n \}} \\ 0 & 1 & … & 0 & 1 & \frac{g \{ 2 , k + 2 \}}{g \{ 2 , k + 1 \}} & … & \frac{g \{ 2 , n \}}{g \{ 2 , k + 1 \}} \\ ⋮ & ⋮ & ⋱ & ⋮ & ⋮ & ⋮ & ⋱ & ⋮ \\ 0 & 0 & … & 1 & 1 & \frac{g \{ k , k + 2 \}}{g \{ k , k + 1 \}} & … & \frac{g \{ k , n \}}{g \{ k , k + 1 \}}\end{matrix} ]}_{k \times n .}$$

6. The method of claim 1, wherein the MDS FEC code operable to enable a recovery of a loss of up to r packets comprising a transmitted set of contiguous or non-contiguous k data packets is a Cauchy-based MDS FEC code that may take the form of a generator matrix of the form
$$G = {[ \begin{matrix}1 & 0 & … & 0 & \frac{1}{1 + ( k + 1 )} & \frac{1}{1 + ( k + 2 )} & … & \frac{1}{1 + n} \\ 0 & 1 & … & 0 & \frac{1}{2 + ( k + 1 )} & \frac{1}{2 + ( k + 2 )} & … & \frac{1}{2 + n} \\ ⋮ & ⋮ & ⋱ & ⋮ & ⋮ & ⋮ & ⋱ & ⋮ \\ 0 & 0 & … & 1 & \frac{1}{k + ( k + 1 )} & \frac{1}{k + ( k + 2 )} & … & \frac{1}{k + n}\end{matrix} ]}_{k \times n} .$$

7. The method of claim 6, wherein after transforming the Cauchy-based MDS FEC code such that the MDS FEC code is further operable to enable encoding of an additional parity packet, a resulting transformed Cauchy-based MDS FEC code may take the form of a transformation matrix of the form
$${G}^{′} = {[ \begin{matrix}1 & 0 & … & 0 & 1 & \frac{1 + ( k + 1 )}{1 + ( k + 2 )} & … & \frac{1 + ( k + 1 )}{1 + n} \\ 0 & 1 & … & 0 & 1 & \frac{2 + ( k + 1 )}{2 + ( k + 2 )} & … & \frac{2 + ( k + 1 )}{2 + n} \\ ⋮ & ⋮ & ⋱ & ⋮ & ⋮ & ⋮ & ⋱ & ⋮ \\ 0 & 0 & … & 1 & 1 & \frac{k + ( k + 1 )}{k + ( k + 2 )} & … & \frac{k + ( k + 1 )}{k + n}\end{matrix} ]}_{k \times n .} .$$

8. The method of claim 1, wherein the forward error correction (FEC) code is extensible such that a first FEC code generator matrix may take a form of (k+r, k) where r is a prescribed number of additional recovery packets and such that a second FEC code generator matrix may take the form of (k+r′, k) where r′ is a different prescribed number of additional recovery packets.

9. The method of claim 8, wherein the first and second data transmissions have different historical packet loss characteristics.

10. A system for providing forward error correction for data transmitted across a network, comprising:
an encoder including a transformed forward error correction (FEC) code being operable to enable a recovery of a loss of up to r packets comprising a transmitted set of contiguous or non-contiguous k data packets and r encoded packets, and one of the encoded packets being a parity packet.

11. The system of claim 10, wherein the FEC code comprises a maximum distance separable (MDS) FEC code wherein only k+r data and encoded packets must be sent across the network to enable recovery of up to r lost data packets.

12. The system of claim 11, wherein the MDS FEC code may be expressed in matrix terms as a (k+r, k) systematic MDS code and wherein a matrix representing the (k+r, k) systematic MDS code is constructed with k rows by (k+r) columns, wherein a k+1 column represents the parity packet.

13. The system of claim 11, wherein the transformed MDS FEC code operable to enable a recovery of a loss of up to any r packets comprising a transmitted set of contiguous or non-contiguous k+r data and coded packets is derived from an original MDS FEC code of a generator matrix of the form
$$G = {[ \begin{matrix}1 & 0 & … & 0 & g\_ \{ 1 , k + 1 \} & g\_ \{ 1 , k + 2 \} & … & g\_ \{ 1 , n \} \\ 0 & 1 & … & 0 & g\_ \{ 2 , k + 1 \} & g\_ \{ 2 , k + 2 \} & … & g\_ \{ 2 , n \} \\ ⋮ & ⋮ & ⋱ & ⋮ & ⋮ & ⋮ & ⋱ & ⋮ \\ 0 & 0 & … & 1 & g\_ \{ k , k + 1 \} & g\_ \{ k , k + 2 \} & … & g\_ \{ k , n \}\end{matrix} ]}_{k \times n .} ,$$
and the transformed NDS FEC code may take the form of a transformation matrix of the form
$${[ \begin{matrix}1 & 0 & … & 0 & 1 & \frac{g \{ 1 , k + 2 \}}{g \{ 1 , k + 1 \}} & … & \frac{g \{ 1 , n \}}{g \{ 1 , k + n \}} \\ 0 & 1 & … & 0 & 1 & \frac{g \{ 2 , k + 2 \}}{g \{ 2 , k + 1 \}} & … & \frac{g \{ 2 , n \}}{g \{ 2 , k + 1 \}} \\ ⋮ & ⋮ & ⋱ & ⋮ & ⋮ & ⋮ & ⋱ & ⋮ \\ 0 & 0 & … & 1 & 1 & \frac{g \{ k , k + 2 \}}{g \{ k , k + 1 \}} & … & \frac{g \{ k , n \}}{g \{ k , k + 1 \}}\end{matrix} ]}_{k \times n .} .$$

14. The system of claim 13, wherein the MDS FEC code is a Cauchy-based MDS FEC code that may take the form of a generator matrix of the form
$$G = {[ \begin{matrix}1 & 0 & … & 0 & \frac{1}{1 + ( k + 1 )} & \frac{1}{1 + ( k + 2 )} & … & \frac{1}{1 + n} \\ 0 & 1 & … & 0 & \frac{1}{2 + ( k + 1 )} & \frac{1}{2 + ( k + 2 )} & … & \frac{1}{2 + n} \\ ⋮ & ⋮ & ⋱ & ⋮ & ⋮ & ⋮ & ⋱ & ⋮ \\ 0 & 0 & … & 1 & \frac{1}{k + ( k + 1 )} & \frac{1}{k + ( k + 2 )} & … & \frac{1}{k + n}\end{matrix} ]}_{k \times n} .$$

15. The method of claim 14, wherein after transforming the Cauchy-based MDS FEC code such that the MDS FEC code is further operable to enable encoding of an additional parity packet, a resulting transformed Cauchy-based MDS FEC code may take the form of a transformation matrix of the form
$${G}^{′} = {[ \begin{matrix}1 & 0 & … & 0 & 1 & \frac{1 + ( k + 1 )}{1 + ( k + 2 )} & … & \frac{1 + ( k + 1 )}{1 + n} \\ 0 & 1 & … & 0 & 1 & \frac{2 + ( k + 1 )}{2 + ( k + 2 )} & … & \frac{2 + ( k + 1 )}{2 + n} \\ ⋮ & ⋮ & ⋱ & ⋮ & ⋮ & ⋮ & ⋱ & ⋮ \\ 0 & 0 & … & 1 & 1 & \frac{k + ( k + 1 )}{k + ( k + 2 )} & … & \frac{k + ( k + 1 )}{k + n}\end{matrix} ]}_{k \times n .} .$$

16. A computer-readable medium containing computer-executable instructions which when executed by a computer perform a method of providing forward error correction in a data transmission system, comprising:
populating an encoder with a forward error correction (FEC) code operable to enable a recovery of a loss of up to all of a set of packets comprising a set of contiguous or non-contiguous n packets, the n packets consisting of k data packets and r encoded packets;
transforming the FEC code such that at least one of the encoded packets in the transformed FEC code is a parity packet, which is the XOR of all k data packets; and
wherein the transformed FEC code is operable to enable a recovery of a loss of up to r packets.

17. The computer-readable medium of claim 16, wherein the FEC code comprises a maximum distance separable (MDS) FEC code wherein only k+r original and coded data packets must be sent across the network to enable recovery of r lost packets.

18. The computer-readable medium of claim 16, wherein if the FEC code is used in a data transmission system wherein the original k data packets and the r encoded packets are transmitted over a network; and
if the original k data packets and the r encoded packets are subjected to network packet losses;
the original k data packets and the r encoded packets are recoverable as long as less than or equal to r packets are lost in the transmission.

19. The computer-readable medium of claim 16, wherein the MDS FEC code may be expressed in matrix terms as a (k+r, k) systematic MDS code and wherein a matrix representing the (k+r, k) systematic MDS code is constructed with k rows by (k+r) columns, wherein a k+1 column represents the parity packet.

20. The computer-readable medium of claim 16, wherein the MDS FEC code is operable to enable a recovery of a loss of up to all r packets comprising a transmitted set of contiguous or non-contiguous n data packets may take the form of a generator matrix of the form
$$G = {[ \begin{matrix}1 & 0 & … & 0 & g\_ \{ 1 , k + 1 \} & g\_ \{ 1 , k + 2 \} & … & g\_ \{ 1 , n \} \\ 0 & 1 & … & 0 & g\_ \{ 2 , k + 1 \} & g\_ \{ 2 , k + 2 \} & … & g\_ \{ 2 , n \} \\ ⋮ & ⋮ & ⋱ & ⋮ & ⋮ & ⋮ & ⋱ & ⋮ \\ 0 & 0 & … & 1 & g\_ \{ k , k + 1 \} & g\_ \{ k , k + 2 \} & … & g\_ \{ k , n \}\end{matrix} ]}_{k \times n .} ,$$
